(19) United States
(12) Patent Application Publication
(10) Pub. No.: US 2025/0210304 A1
(43) Pub. Date: Jun. 26, 2025

(54) Electrode and Coil Configurations For Processing Chambers and Related Chamber Kits, Apparatus, and Methods For Semiconductor Manufacturing

(71) Applicant: Applied Materials, Inc., Santa Clara, CA (US)

(72) Inventors: Ala MORADIAN, Sunnyvale, CA (US); Ananth Nuggehalli BHOJ, Round Rock, TX (US); Prashanth KOTHNUR, San Jose, CA (US); Saurabh CHOPRA, Santa Clara, CA (US); Yunho KIM, Milpitas, CA (US)

(21) Appl. No.: 18/391,423

(22) Filed: Dec. 20, 2023

(51) Int. Cl. H01J 37/32; C23C 16/46; C23C 16/509; C23C 16/52

(52) U.S. Cl. CPC H01J 37/3211; C23C 16/46; C23C 16/509; C23C 16/52; H01J 37/32146; H01J 37/32165; H01J 37/32522; H01J 37/3255; H01J 37/32568; H01J 2237/3321; H01J 2237/3323

(57) ABSTRACT

Embodiments disclosed herein generally provide improved deposition uniformity in processing chambers. In one embodiment which can be combined with other embodiments, a processing chamber applicable for use in semiconductor manufacturing is provided. The processing chamber includes a chamber body comprising an inject section and an exhaust section. The processing chamber also includes a plate having an opaque surface. The chamber body and the plate at least partially define a processing volume. The processing chamber includes one or more heat sources operable to heat the processing volume, a substrate support disposed in the processing volume, and one or more coils disposed between the substrate support and a lid of the processing chamber.

### BACKGROUND

### Field

The present disclosure generally relates to electrode configurations for processing chambers, coil configurations for processing chambers, and related chamber kits, apparatus, methods, and components for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Operations can also be limited with respect to application modularity. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure generally relates to electrode and coil configurations for processing chambers, and related chamber kits, apparatus, methods, and components for semiconductor manufacturing. Embodiments disclosed herein generally provide improved deposition uniformity in processing chambers.

In one embodiment which can be combined with other embodiments, a processing chamber applicable for use in semiconductor manufacturing is provided. The processing chamber includes a chamber body comprising an inject section and an exhaust section. The processing chamber also includes a plate having an opaque surface. The chamber body and the plate at least partially define a processing volume. The processing chamber includes one or more heat sources operable to heat the processing volume, a substrate support disposed in the processing volume, and one or more coils disposed between the substrate support and a lid of the processing chamber.

In one embodiment which can be combined with other embodiments, a chamber kit applicable for use in semiconductor manufacturing is provided. The chamber kit includes a liner comprising an inner face and a plate. The plate is sized and shaped for disposition within the liner. The plate includes an electrode disposed in the plate.

In one embodiment which can be combined with other embodiments, a processing chamber applicable for use in semiconductor manufacturing is provided. The processing chamber includes a chamber body, a plate, a substrate support, one or more coils and a controller. The chamber body includes an inject section and an exhaust section. The plate and the chamber body at least partially define a processing volume. The one or more heat sources are operable to heat the processing volume. The substrate support is disposed in the processing volume. The one or more coils are disposed between the substrate support and a lid of the processing chamber. The controller includes a memory. The memory includes instruction that, when executed by a processor, cause a plurality of operations to be conducted. The plurality of operations include flowing an electrical current through the one or more coils, heating the processing volume, and flowing one or more process gases into the processing volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic side cross-sectional view of a processing chamber, according to one or more embodiments.

FIG. 2 is a schematic side cross-sectional view of a processing chamber, according to one or more embodiments.

FIG. 3 is a schematic partial top view of one or more coils and a plate shown in FIG. 1, according to one or more embodiments.

FIG. 4 is a schematic partial top view of a plate and electrode shown in FIG. 2, according to one or more embodiments.

FIG. 5 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to electrode configurations for processing chambers, and related chamber kits, apparatus, methods, and components for semiconductor manufacturing. In one embodiment which can be combined with other embodiments, the electrode configurations are used to generate plasma to activate gases in relatively low temperature epitaxial deposition operations.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

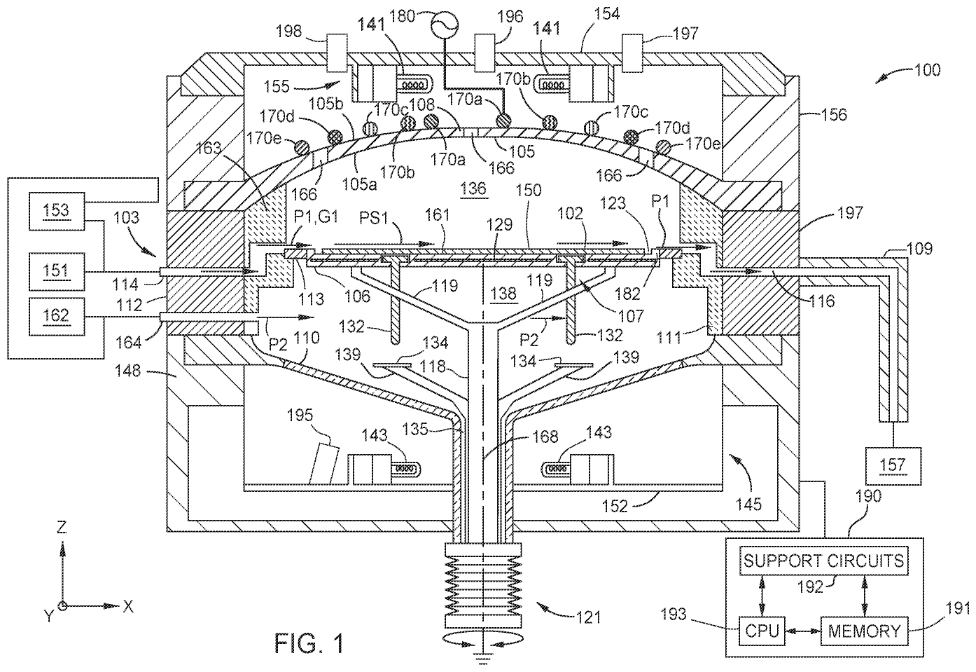

FIG. 1 is a schematic side cross-sectional view of a processing chamber 100, according to one or more embodiments. The processing chamber 100 is a deposition chamber. In one embodiment which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a first plate 108 (such as an upper plate, e.g., an upper window for example an upper dome), a second plate 110 (such as a lower plate, e.g., a lower window for example a lower dome), and one or more heat sources 141, 143. The one or more heat sources 141, 143 include a plurality of upper heat sources 141 and a plurality of lower heat sources 143. The one or more heat sources 141, 143 are operable to heat the processing volume 136. In one embodiment which can be combined with other embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the first plate 108 and the second plate 110. The substrate support 106 supports the substrate 102. In one embodiment which can be combined with other embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the first plate 108 and a lid 154. The plurality of upper heat sources 141 form a portion of the upper heat source module 155.

The plurality of lower heat sources 143 are disposed between the second plate 110 and a floor 152. The plurality of lower heat sources 143 form a portion of a lower heat source module 145. The first plate 108 may be an upper dome and/or is formed of an energy transmissive material, such as quartz. The second plate 110 may be a lower dome and/or is formed of an energy transmissive material, such as quartz.

A processing volume 136 and a purge volume 138 are formed between the first plate 108 and the second plate 110. The processing volume 136 and the purge volume 138 are part of an internal volume defined at least partially by the first plate 108, the second plate 110, and one or more liners 111, 163. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one embodiment which can be combined with other embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The flow module 112 is part of an inject section 103. The inject section 103 also includes the one or more gas inlets 114. The one or more gas inlets 114 and the one or more purge gas inlets 164 are disposed on the opposite side from the one or more gas exhaust outlets 116.

A pre-heat ring 113 is disposed below the one or more gas inlets 114 and the one or more gas exhaust outlets 116. The pre-heat ring 113 includes a complete ring or one or more ring segments. The pre-heat ring 113 is disposed above the one or more purge gas inlets 164. The one or more liners 111, 163 are disposed on an inner surface of the flow module 112 and protect the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H), Fluorine (F₂), and/or chlorine (Cl). In one embodiment which can be combined with other embodiments, the one or more process gases P1 include silicon phosphide (SiP) and/or phospine (PH₃), and the one or more cleaning gases include hydrochloric acid (HCl). A gas G1 may be supplied to the processing volume 136, and the gas G1 is ignited into a plasma PS1 in the processing volume 136. The gas G1 used to generate the plasma PS1 may include but is not limited to one or more of: hydrogen (H₂), xenon (Xe₂), fluorine (F₂), krypton fluoride (KrF), neon (Ne), and/or any mixtures thereof (such as xenon and neon). In one embodiment which can be combined with other embodiments, the gas G1 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one embodiment which can be combined with other embodiments, the gas G1 includes one or more dopant gases, such as germane, diborane, and/or phosphorous. Other gases are contemplated for the gas G1.

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112. The one or more gas exhaust outlets 116 and the exhaust system 109 form a 104 exhaust section. In one embodiment which can be combined with other embodiments, the inject section 103 is disposed on the opposite side of the process chamber 100 from the exhaust section 104.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one embodiment which can be combined with other embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one embodiment which can be combined with other embodiments, the one or more sensor devices 195, 196, 197, 198 each include a sensor that includes one or more of silicon (Si), carbon (C), gallium (Ga), and/or nitrogen (N). In one embodiment which can be combined with other embodiments, the one or more sensor devices 195, 196, 197, 198 each include a silicon sensor, a silicon carbide (SiC) sensor, and/or a gallium nitride (GaN) sensor. In one embodiment which can be combined with other embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. In one embodiment which can be combined with other embodiments, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one embodiment which can be combined with other embodiments, one or more of the sensor devices 195, 196, 197, 198 include a residual gas analyzer, an optical emission spectrometer, an enthalpy probe, a Langmuir probe, a Faraday cup, and/or an absorption spectrometer.

In one embodiment which can be combined with other embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one embodiment which can be combined with other embodiments, the system including the process chamber 100 includes any one, any two, or any three of the four illustrated sensor devices 195, 196, 197, 198. In one embodiment which can be combined with other embodiments, the process chamber 100 includes one or more additional sensor devices, in addition to the sensor devices 195, 196, 197, 198. In one embodiment which can be combined with other embodiments, the process chamber 100 may include sensor devices disposed at different locations and/or with different orientations than the illustrated sensor devices 195, 196, 197, 198.

The processing chamber 100 includes a radio frequency (RF) generator 180 and one or more coils 170. The RF generator 180 is coupled to one or more coils 170. The RF generator 180 is operable to pass current through the one or more coils 170 and inductively generate plasma PS1 in the processing volume 136.

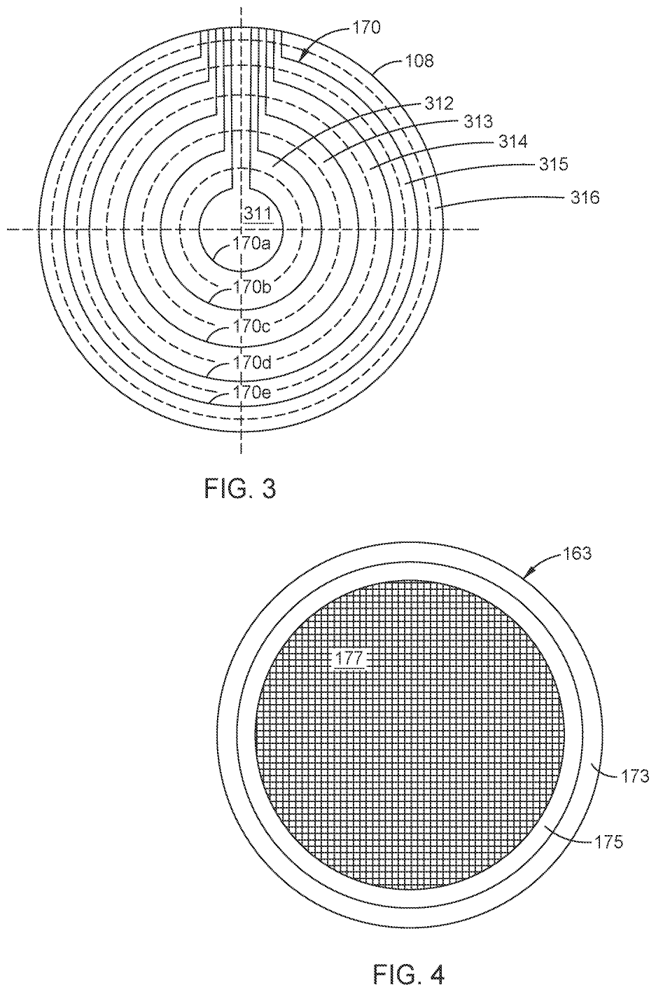

In one embodiment which can be combined with other embodiments, the one or more coils 170 are coupled to the first plate 108. The one or more coils 170 are disposed between the substrate support 106 and the lid 154. In one or more embodiments, the one or more coils 170 are disposed between the first plate 108 and the lid 154. The one or more coils 170 are RF coils. In one embodiment which can be combined with other embodiments, the one or more coils 170 are supported at least partially by the first plate 108. The one or more coils 170 may be inductive coils configured to inductively generate plasma PS1 in the processing volume 136. In one embodiment which can be combined with other embodiments, the one or more coils 170 are disposed (e.g., embedded) within the first plate 108. The one or more coils 170 may be one or more separate coils. For example, the one or more coils 170 may include a first coil 170a, a second coil 170b, a third coil 170c, a fourth coil 170d, and a fifth coil 170e. While illustrated as five coils, other numbers of coils are contemplated. For example, the one or more coils 170 may include 2 coils, 3 coils, 4 coils, 5 coils, or 6 or more coils. The one or more coils 170 are described in more detail in the description of FIG. 3.

In one embodiment which can be combined with other embodiments, the plurality of lower heat sources 143 provide heat to the processing chamber 100 while the one or more coils 170 inductively generate plasma PS1 in the processing volume 136. In one embodiment which can be combined with other embodiments, the processing chamber 100 is heated from the plurality of lower heat sources 143 such that the plurality of upper heat sources 141 may be omitted.

The first plate 108 includes a first surface 105a and a second surface 105b. In one embodiment that may be combined with other embodiments, the first plate 108 is formed at least partially of an opaque material, such as SiC and/or black quartz. For example, an entirety of the first plate 1008 is formed of an opaque material. In one embodiment that may be combined with other embodiments, the first surface 105a and/or the second surface 105b of the first plate 108 is an opaque surface. In one embodiment that may be combined with other embodiments, the first surface 105a and/or the second surface 105b include an opaque coating, such as a silicon carbide (SiC) coating and/or a black quartz coating. An opaque first plate 108 enables enhanced uniformity during deposition because the effect of shadows from components between the lid 154 and the first plate 108 is reduced or eliminated. For example, uniformity is enhanced by a reduction in shadows caused as energy from the plurality of upper heat sources 141 passes around the one or more coils 170 disposed between the first plate 108 and the plurality of upper heat sources 141. In one or more embodiments, the first plate 108 includes transparent sections 166 aligned respectively with sensors devices 196, 197, 198.

In one embodiment that may be combined with other embodiments, the processing chamber 100 includes an electrode 129. The electrode 129 is coupled to (e.g., disposed within, such as embedded in) the substrate support 106. The electrode 129 can include, for example, a mesh, such as a metallic mesh. In one embodiment that may be combined with other embodiments, current flows between the one or more coils 170 and the electrode 129 to generate plasma PS1 in the processing volume 136 in a capacitively-coupled manner. In one embodiment that may be combined with other embodiments, the one or more coils 170 and the first electrode 129 are operable to flow a current across at least part of the processing volume 136 to capacitively generate plasma in the processing volume 136. The electrode 129 can be omitted. For example, the electrode 129 can be omitted and the one or more coils 170 can be used to inductively generate plasma PS1 in the processing volume 136.

The process chamber 100 may include an ion filter. The Ion filter can be used to remove ions from the generated plasma. The present disclosure contemplates that an ion filter can be positioned such that the ion filter filters ions from the plasma PS1 prior to the plasma PS1 flowing over the substrate 102. The ion filter can include a conductive material including, for example, silicon carbide (SiC), molybdenum, tungsten, stainless steel, and/or aluminum (such as anodized aluminum). The ion filter can include an ion blocker plate.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, and the heater within the pre-heat ring 113.

The controller 190 includes a central processing unit (CPU) 193 (e.g., a processor), a memory 191 containing instructions, and support circuits 192 for the CPU 193. The controller 190 controls various items directly, or via other computers and/or controllers. In one embodiment which can be combined with other embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the heat sources 141, 143, an electrical power applied to the one or more coils 170 and/or the electrode 129, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations (such as the operations of the method 500) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

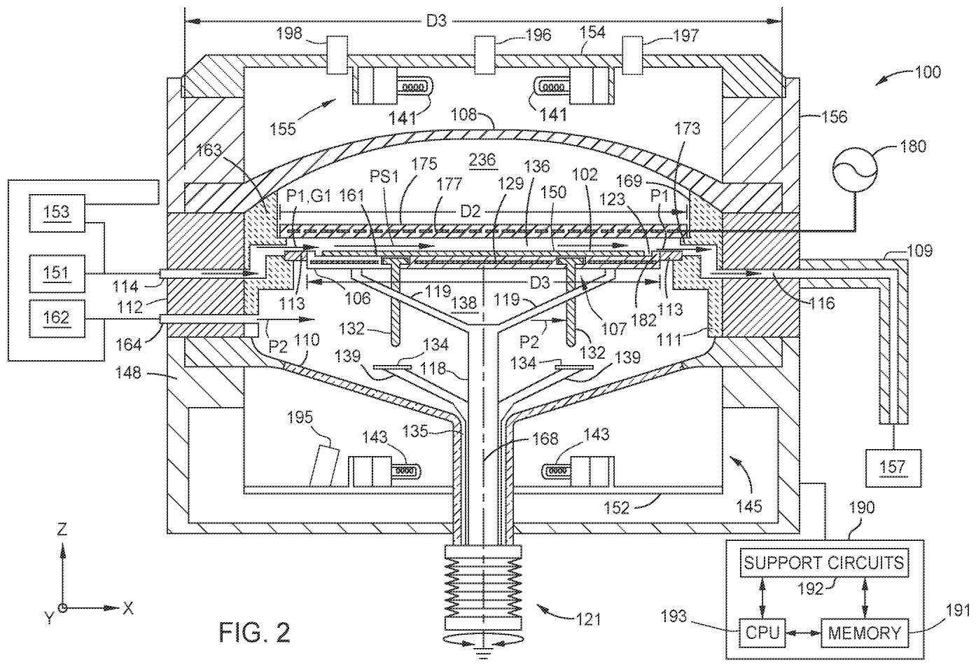

The controller 190 is configured to control power to the one or more heaters 141, 143; power to the RF generator 180; the current and signal to the one or more coils 170, the electrode 129, a second electrode 177 (shown in FIG. 2); the deposition; the cleaning; the rotational position; the heating; and gas flow through the processing chamber 100 by providing an output to the controls for the sensor devices 195, 196, 197, 198, the RF generator 180, and/or the one or more heaters, the upper heat sources 141, the lower heat sources 143, the process gas source 151, the purge gas source 162, the motion assembly 121, and/or the exhaust pump 157.

FIG. 2 is a schematic side cross-sectional view of a processing chamber 200 according to one or more embodiments. The processing chamber 200 is similar to the processing chamber 100 in FIG. 1, and includes one or more aspects, features, components, operations, and/or properties thereof.

The electrode 129 can be referred to as a first electrode, and the processing chamber 200 includes the second electrode 177. The electrode 129 is coupled to ground, for example, through a conductive rod 168 coupled to ground. In one or more embodiments, in FIG. 2 the first plate 108 is formed at least partially of an energy transmissive material, such as quartz (e.g., transparent quartz). In one embodiment which can be combined with other embodiments, the first plate 108 is a window. The processing chamber 200 includes a third plate 175. The third plate 175 is disposed in the internal volume and between the first plate 108 and substrate support 106. In one embodiment that may be combined with other embodiments, that third plate 175 is an isolation plate that isolates the processing volume 136 from a volume 236 between the third plate 175 and the first plate 108. The third plate 175 is sized and shaped to be placed on a first ledge 173 of an inner face 179 of the upper liner 163. The first plate 108 has an outer dimension D1 (e.g., an outer diameter). The third plate 175 has an outer dimension D2 (e.g., an outer diameter) less than the outer dimension D1 of the first plate 108 and greater than an outer dimension D3 (e.g., an outer diameter) of the substrate support 106.

In one embodiment which can be combined with other embodiments, the third plate 175 is formed of an energy transmissive material, such as quartz (e.g., transparent quartz). In one embodiment which can be combined with other embodiments, the third plate 175 is formed at least partially of an opaque material, such as SiC or black quartz.

The third plate 175 enhances the utilization of process gas P1 by reducing the processing volume 136. The enhanced utilization of process gas P1 reduces costs of operation and manufacturing.

The third plate 175 includes a second electrode 177. The second electrode 177 is coupled to the third plate 175. In one embodiment which can be combined with other embodiments, the second electrode 177 is disposed within (e.g., embedded in) the third plate 175. The second electrode 177 may be a mesh electrode. For example, the second electrode can be a metallic electrode with a lattice structure (such as a grid structure). The second electrode 177 is coupled to the RF generator 180. The RF generator 180 is operable to pass current from the second electrode 177 to the first electrode 129 and generate plasma PS1 in the processing volume 136, between the third plate 175 and the substrate support 106. In embodiment(s) where the third plate 175 includes SiC, the second electrode 177 is also operable supply heat to the substrate 102 by flowing electrical current to the second electrode 177 because the third plate 175 functions as a resistive heater. In one embodiment that may be combined with other embodiments, the second electrode 177 is a passive electrode and the upper heat sources 141 heat the third plate 175 with infrared energy. The third plate 175 is described in more detail in the description of FIG. 4.

In one embodiment that may be combined with other embodiments, the second electrode 177 and the first electrode 129 are operable to flow a current across at least part of the processing volume 136 to generate plasma in the processing volume 136 in a capacitively coupled manner. In one embodiment that may be combined with other embodiments, the second electrode 177 and the first electrode 129 are capacitive meshes and generate plasma when current travels between the second electrode 177 of the third plate 175 and the first electrode 129. The current can flow from the second electrode 177 and to the first electrode 129 (as shown), or the current can flow from the first electrode 129 and to the second electrode 177. The processing chamber 100 can be heated by both the plurality of upper heat sources 141 and the plurality of lower heat sources 143.

FIG. 3 is a schematic partial top view of the one or more coils 170 and the first plate 108 shown in FIG. 1, according to one or more embodiments. As illustrated the one or more coils 170 are arranged in a curved pattern (e.g., circular pattern. For example, the second coil 170b is disposed around and radially outward of first coil 170a.

The one or more coils 170 may include a plurality of coils that are positioned respectively in a plurality of zones 310. The plurality of zones 310 correspond and are aligned respectively with portions of the substrate support 106 (FIG. 1). The plurality of zones 310 may include some or all of at least a first zone 311, a second zone 312, a third zone 313, a fourth zone 314, a fifth zone 315, and a sixth zone 316. More or less zones are contemplated.

In one embodiment which may be combined with other embodiments, the first coil 170a corresponds with the first zone, the second coil 170b corresponds with the second zone, and third coil 170c corresponds with the third zone. The fourth coil 170d corresponds with the fourth zone, and the fifth coil 170e correspond with the fifth zone. The second zone and the second coil 170b are disposed radially outwardly of the first zone and the first coil 170a, and the third zone and the third coil 170c are disposed radially outwardly of the second zone and the second coil 170b. The fourth zone and the fourth coil 170d are disposed radially outwardly of the third zone and the third coil 170c, and the fifth zone and the fifth coil 170e are disposed radially outwardly of the fourth zone and the fourth coil 170e. An outer edge of the first plate 108 is disposed radially outwardly of the fifth coil 170e.

The RF generator 180 (FIG. 1) flows one or more currents to the one or more coils 170. The controller 190 (FIG. 1) is operable to independently control the amount of current, the frequency, and/or the phase of the current to each of the one or more coils 170.

In one embodiment which may be combined with other embodiments, the electrical current is an RF current. For example, the RF generator 180 (FIG. 1) flows a first current to the first coil 170a and flows a second current to the second coil 170b. In one embodiment which may be combined with other embodiments, the first current of the one or more currents has a frequency about the same as the second current. For example, the frequency of the first current is within a difference of 5% or less of the second current.

In one embodiment which may be combined with other embodiments, the frequency and/or amplitude of the first current is lower than the frequency and/or amplitude of the second current. For example, the frequency of each current increases across the coils in a radially outward direction. For example, the frequency and/or amplitude of each of the one or more coils 170 increases for each coil from the first coil 170a to the fifth coil 170e. For example, the frequency and/or amplitude of the current of a coil is greater by 5% or more than the adjacent radially inward coil. The frequency of the first current may be about 40 kHz to about 2.45 GHZ. For example the frequency of the first current may be about 40 kHz, about 13.56 MHZ, and/or about 2.45 GHz.

In one embodiment which can be combined with other embodiments, the frequency and/or amplitude of a current applied to the outermost coil 170e is greater than the first current applied to the first coil 170a.

In one embodiment which may be combined with other embodiments, the frequency and/or amplitude of the first current is greater than the frequency and/or amplitude of the second current. For example, the frequency and/or amplitude of each current increases across the coils in a radially inward direction. For example, the frequency and/or amplitude of each of the one or more coils 170 decreases for each coil from the first coil 170a to the fifth coil 170e. For example, the frequency and/or amplitude of the current of a coil is greater by 5% or more than the adjacent radially outward coil.

In one embodiment which may be combined with other embodiments, the first current and/or second current is at least partially defined by a pulsed signal. The pulsed signal may be an on and off signal where flow of electrical current from the RF generator 180 (FIG. 1) starts and stops.

In one embodiment which may be combined with other embodiments the RF generator 180 (FIG. 1) flows an alternating current to the one or more coils 170. In one embodiment which may be combined with other embodiments the RF generator 180 (FIG. 1) flows a direct current to the one or more coils 170. In one embodiment which may be combined with other embodiments, the direct current and/or the alternating current is at least partially defined by a pulsed signal.

FIG. 4 is a schematic partial top view of the third plate 175 and the second electrode 177 shown in FIG. 2, according to one or more embodiments. The third plate 175 includes the second electrode 177 disposed within the third plate 175.

In one embodiment which may be combined with other embodiments, the third plate 175 is part of a chamber kit applicable for use in semiconductor manufacturing. The chamber kit can include for example the upper liner 163, the third plate 175, and the second electrode 177. The third plate 175 is sized and shaped for disposition within the inner face 179 (FIG. 2) of the upper liner 163.

In one embodiment which may be combined with other embodiments, the second electrode 177 is a mesh electrode encapsulated by the third plate 175. In one embodiment which may be combined with other embodiments, the second electrode 177 of the third plate 175 is a capacitive mesh. In one embodiment which may be combined with other embodiments, a power to the second electrode 177 is reduced to about 0 watts and deposition may occur as thermal epitaxy process.

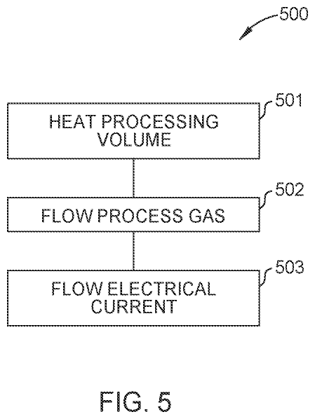

FIG. 5 is a schematic block diagram view of a method 500 of substrate processing for semiconductor manufacturing, according to one or more embodiments.

The method 500 includes an operation 501 where the processing volume 136 is heated. In one embodiment which may be combined with other embodiments, the substrate 102 is heated to a target temperature of 400 degrees Celsius or higher or 600 degrees Celsius or less. In one embodiment which may be combined with other embodiments, the target temperature for the substrate 102 is within a range of 380 degrees Celsius to 600 degrees Celsius, for example 400 degrees Celsius to 500 degrees Celsius. In one embodiment which may be combined with other embodiments, the target temperature for the substrate 102 is less than 500 degrees Celsius. In one embodiment which may be combined with other embodiments, the target temperature for the substrate 102 is 400 degrees Celsius or less, such as less than 200 degrees Celsius (for example about 150 degrees Celsius). The heating is accomplished by at least one of the plurality of upper heat sources 141 (FIG. 1) and/or the plurality of lower heat sources 143. In embodiments where the first plate 108 is opaque, the shadow effect from the upper heat sources 141 can be reduced or eliminated, thereby enhancing deposition uniformity during operation.

At operation 502, process gas P1 is flowed into the processing volume 136. In one embodiment which may be combined with other embodiments, operation 502 includes maintaining the processing volume at a pressure. In one embodiment which may be combined with other embodiments, the pressure is maintained to be less than 60 Torr, such as within a range of 0 Torr to 30 Torr. In one embodiment which may be combined with other embodiments, the pressure is maintained to be less than 1 Torr, such as within a range of 0 Torr to 5 mTorr.

At operation 503, the RF generator 180 flows electrical current to the one or more coils 170 and/or the second electrode 177 to generate a plasma in the processing volume 136.

Benefits of the present disclosure include reliable gas activation; adjustability of gas activation (such as at relatively low processing temperatures); reliable plasma generation and reduced or eliminated shadowing effects; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation). Benefits also include enhanced deposition uniformity, reduced divertive gas flow, and reduction of processing volume size.

Benefits also include enhanced device performance; reduced or eliminated occurrences of unintended dopant diffusions; efficient processing; and increased throughput. It is contemplated that one or more aspects disclosed herein may be combined. As an example, one or more aspects, features, components, operations and/or properties of the processing chamber 100; the controller 190; the one or more sensor devices 195, 196, 197, 198; the first plate 108; the second plate 110; the one or more coils 170; the third plate 175; the first electrode 129; the second electrode 177; and/or the method 500 may be combined.

While the foregoing is directed to embodiments of the present disclosure, other and further embodiments of the disclosure may be devised without departing from the basic scope thereof, and the scope thereof is determined by the claims that follow

What is claimed is:

1. A processing chamber applicable for use in semiconductor manufacturing, comprising:
a chamber body comprising an inject section and an exhaust section;
a plate, the plate comprising an opaque surface, and the chamber body and the plate at least partially defining a processing volume;
one or more heat sources operable to heat the processing volume;
a substrate support disposed in the processing volume; and
one or more coils disposed between the substrate support and a lid of the processing chamber.

2. The processing chamber of claim 1, wherein the one or more coils are disposed between the plate and the lid.

3. The processing chamber of claim 1, wherein the one or more coils are radio frequency (RF) coils.

4. The processing chamber of claim 1, wherein the one or more coils are supported by the plate.

5. The processing chamber of claim 1, wherein the substrate support comprises a first electrode, and the one or more coils and the first electrode are operable to flow a current across at least part of the processing volume to generate plasma in the processing volume.

6. The processing chamber of claim 1, wherein the one or more coils comprise a plurality of coils aligned respectively with a plurality of zones of the substrate support.

7. The processing chamber of claim 1, wherein the plate is formed of an opaque material.

8. The processing chamber of claim 1, wherein the one or more coils comprise:
a first coil operable to flow a first current at a first frequency; and
a second coil operable to flow a second current at a second frequency.

9. A chamber kit applicable for use in semiconductor manufacturing, the chamber kit comprising:
a liner comprising an inner face;
a plate sized and shaped for disposition within the liner, the plate comprising an electrode disposed in the plate.

10. The chamber kit of claim 9, wherein the plate comprises transparent quartz.

11. The chamber kit of claim 9, wherein the electrode in the plate includes a mesh electrode.

12. The chamber kit of claim 9, further comprising a window comprising a transparent material, the window having an outer dimension that is larger than an outer dimension of the plate.

13. The chamber kit of claim 9, wherein the plate includes silicon carbide (SiC), and the electrode is embedded in the SiC.

14. A processing chamber applicable for use in semiconductor manufacturing, comprising:
a chamber body comprising an inject section and an exhaust section;
a plate, and the chamber body and the plate at least partially defining a processing volume;
one or more heat sources operable to heat the processing volume;
a substrate support disposed in the processing volume;
one or more coils disposed between the substrate support and a lid of the processing chamber; and
a controller comprising a memory, the memory comprising instruction that, when executed by a processor, cause a plurality of operations to be conducted, the plurality of operations comprising:
flowing an electrical current through the one or more coils;
heating the processing volume; and
flowing one or more process gases into the processing volume.

15. The processing chamber of claim 14, wherein the electrical current is a radio frequency (RF) current, and the electrical current comprises:
a first current flowed to a first coil of the one or more of coils; and
a second current flowed to a second coil of the one or more of coils.

16. The processing chamber of claim 15, wherein a frequency of the first coil is about the same as a frequency of the second coil.

17. The processing chamber of claim 15, wherein a first frequency of first current to the first coil is lower than a second frequency of the second current to the second coil.

18. The processing chamber of claim 15, wherein the first current is at least partially defined by a pulsed signal.

19. The processing chamber of claim 14, wherein the electrical current includes direct current.

20. The processing chamber of claim 14, wherein the electrical current is at least partially defined by a pulsed signal.
